(19) United States
(12) Patent Application Publication
(10) Pub. No.: US 2019/0319645 A1
(43) Pub. Date: Oct. 17, 2019

(54) METHOD AND DEVICE FOR CORRECTING LOW-LATENCY ERRORS FOR RETRIEVING DATA PACKETS

(71) Applicant: EXPWAY, Paris (FR)

(72) Inventors: Tuan TRAN THAI, Paris (FR); Christophe BURDINAT, Villeurbanne (FR); Cédric THIENOT, Paris (FR)

(73) Assignee: EXPWAY, Paris (FR)

(21) Appl. No.: 16/471,901

(22) PCT Filed: Dec. 21, 2017
(86) PCT No.: PCT/FR2017/053795

§ 371 Date: Jun. 20, 2019

(30) Foreign Application Priority Data
Dec. 22, 2016 (FR) 16 63227

(51) Int. Cl. H03M 13/25; H03M 13/37; H03M 13/35; H03M 13/13

(52) U.S. Cl. CPC H03M 13/251; H03M 13/13; H03M 13/353; H03M 13/3769

(57) ABSTRACT

The invention relates to a method for transmitting data, comprising the steps of: encoding data to be transmitted in the form of source symbols (S) grouped into a data block (DB), distributing the source symbols of the data block in sub-blocks (SB), calculating for each sub-block a respective repair symbol (R1-R9) by a linear combination of source symbols of the sub-block, and transmitting the data block in a stream of data blocks, by successively transmitting each sub-block of the data block, each sub-block being transmitted by transmitting the source symbols of the sub-block, followed by the repair symbol of the sub-block.

The present invention relates to the transmission of data in a communication channel between a transmitting device and a receiving device, and in particular, the implementation of a correction mechanism for data errors or loss.

Many error correction codes have been proposed to ensure the reliability of file or data stream transmissions through transmission channels introducing data loss or corruption.

In the field of mobile networks, and in particular in point-to-multipoint and broadcast communications, the Forward Error Correction Applicative Layer AL-FEC plays a key role in ensuring a reliable distribution of large-scale content. AL-FEC has even been defined as mandatory by the 3rd Generation Partnership Project (3GGP) for Extended Multimedia Broadcast Services (eMBMS). Reed-Solomon (RS) coding is commonly used among the codes used for AL-FEC error correction. This coding scheme belongs to the category of Maximum Distance Separable (MDS) codes which can reconstitute k source symbols out of n transmitted symbols including n-k repair symbols. In the case of a packet data transmission protocol, files, data streams, or data blocks are transmitted in the form of data packets divided into symbols which may or may not be of the same size. The size of a symbol can be expressed by a number of bits. The repair symbols RS are obtained by operations performed over a Galois field GF such as GF(2^{m}). Thus, the repair symbols are computed by a linear combination of the source symbols using coefficients belonging to GF(2^{m}). Typically, repair symbol calculations are performed over GF(2⁸), which limits the size n of the processed data blocks to less than 256 symbols.

The AL-FEC block encodings have the drawback of requiring to wait for the repair symbols transmitted at the end of a data block for restoring a lost or erroneous symbol in the data block. The recovery delay of a source symbol can therefore reach the reception time of a data block, when the error occurs on the first source symbol of the data block. Similarly, the access delay to a stream of data blocks can reach the duration of reception of a block when the access time to the stream occurs between the times when the first and second source symbols begin. On the other hand, all the source symbols of a data block have the same high level of protection, since all the repair symbols are calculated from all the source symbols of the block.

There are other codes such as Low-Density Parity Check (LDPC), Raptor/RaptorQ that support larger block sizes. However, in real-time applications, latency constraints limit the size of the data blocks. Block-based AL-FEC codes are widely used because of their multiple performance advantages, particularly in terms of repair capacity, complexity and flexibility. On the other hand, block-based AL-FEC codes have a high latency of repair. If one of the first symbols in a data block is erroneous or lost, it cannot be restored until the repair symbols at the end of the block are received.

Convolutional codes have also been proposed, applying a sliding window mechanism. According to such codes, the repair symbols are computed on the fly, on the source symbols belonging to the sliding window, and sent after the source symbols of the window. For example, a repair symbol is calculated on at most W source symbols and sent every k source symbols, k<W. The recovery of a lost or erroneous source symbol can therefore be performed as soon as a repair symbol is received, before all source symbols are received. In return, this type of code raises an access latency problem, when a terminal accesses a data stream of a broadcast or point-to-multipoint transmission, after the transmission has started. Indeed, the terminal must wait at least W source symbols before receiving the first usable repair symbol. In addition, each loss of a source symbol increases the access delay to the data stream by k+1 source symbols. A drifting effect occurs when the symbol loss rate approaches the ratio of the number of repair symbols to the number of source symbols transmitted. In this case, it is not possible to restore lost or erroneous symbols.

It is therefore desirable to provide a code having a low latency for restoring a lost or erroneous source symbol, while offering low access latency, and a sufficient level of protection for each source symbol.

Embodiments are provided for a data transmission method, comprising the steps of encoding data to be transmitted in the form of source symbols grouped into data blocks, assigning each data block a number of repair symbols, and for each block of data: distributing the source symbols of the data block into sub-blocks, the number of sub-blocks being equal to the number of repair symbols allocated to the data block, assigning a repair symbol to each sub-block of the data block, calculating the repair symbol of each sub-block of the data block by a linear combination of source symbols of the sub-block and source symbols of preceding sub-blocks in the data block, and transmitting the data block in a stream of data blocks, successively transmitting each sub-block of the data block, each sub-block being transmitted by transmitting the source symbols of the sub-block, followed by the repair symbol of the sub-block.

According to an embodiment, each repair symbol of the data block is computed by a linear combination of at least a portion of the source symbols of the data block, so that each source symbol of the data block is used to calculate a number equal or different by one of repair symbols of the data block.

According to an embodiment, each repair symbol of the data block is computed by a linear combination of all previously transmitted source symbols of the data block.

According to an embodiment, a plurality of repair symbols calculated from at least a part of the source symbols of the last sub-block of the data block, are transmitted at the end of the data block.

According to an embodiment, each sub-block of the data block comprises a number equal or different by one of source symbols.

According to an embodiment, the data block comprises as many sub-blocks as repair symbols transmitted at the end of the data block.

According to an embodiment, the method comprises steps for defining a format of the data block: defining a first number of repair symbols to be transmitted at the end of the data block, determining a number of sub-blocks of the data block according to the first number and a number of repair symbols assigned to the data block, or determining the number of repair symbols assigned to the data block according to the number of sub-blocks of the data block and the first number, calculating a minimum number of source symbols per sub-block by dividing the number of source symbols in the data block by the number of sub-blocks, the minimum number of source symbols being set equal to the greatest integer less than or equal to the result obtained from the division, and calculating a difference between the number of source symbols of the data block and the product of the number of sub-blocks in the data block by the minimum number of source symbols per sub-block, the difference defining a number of source symbols to be added in the sub-blocks of the data block.

According to an embodiment, the method comprises the steps of: receiving from a user terminal in a point-to-point mode, a message signaling poor reception conditions, and transmitting to the terminal in point-to-point mode, in response to the message, at least one repair symbol for each data block transmitted after receiving the message.

Embodiments may also relate to a method for receiving data transmitted in accordance with the previously defined transmission method, the reception method comprising successive steps of receiving the sub-blocks of source symbols of a data block, the reception of each sub-block being followed by the reception of a repair symbol associated with the sub-block, each repair symbol corresponding to a linear combination of the source symbols of the sub-block associated with the repair symbol.

According to an embodiment, the receiving method comprises the steps of: detecting a missing or erroneous source symbol in the data block, and upon receipt of a first repair symbol following the missing or erroneous source symbol, calculating the missing or erroneous source symbol by solving an equation resulting from the equality between the first repair symbol and a linear combination corresponding to the first repair symbol.

According to an embodiment, the reception method comprises the steps of: detecting bad reception conditions of data blocks transmitted in a multi-cast mode, transmitting in a point-to-point mode, to a server, a message signaling poor reception conditions, and receiving in point-to-point mode, for data blocks received in the multi-cast mode, additional repair symbols usable for calculating missing source symbols in the received data blocks.

Embodiments may also relate to a data transmission device configured to implement the previously defined transmission method.

Embodiments may also relate to a data receiving device configured to implement the reception method defined above.

Exemplary embodiments of the invention will be described in the following, without limitation in connection with the attached figures among which:

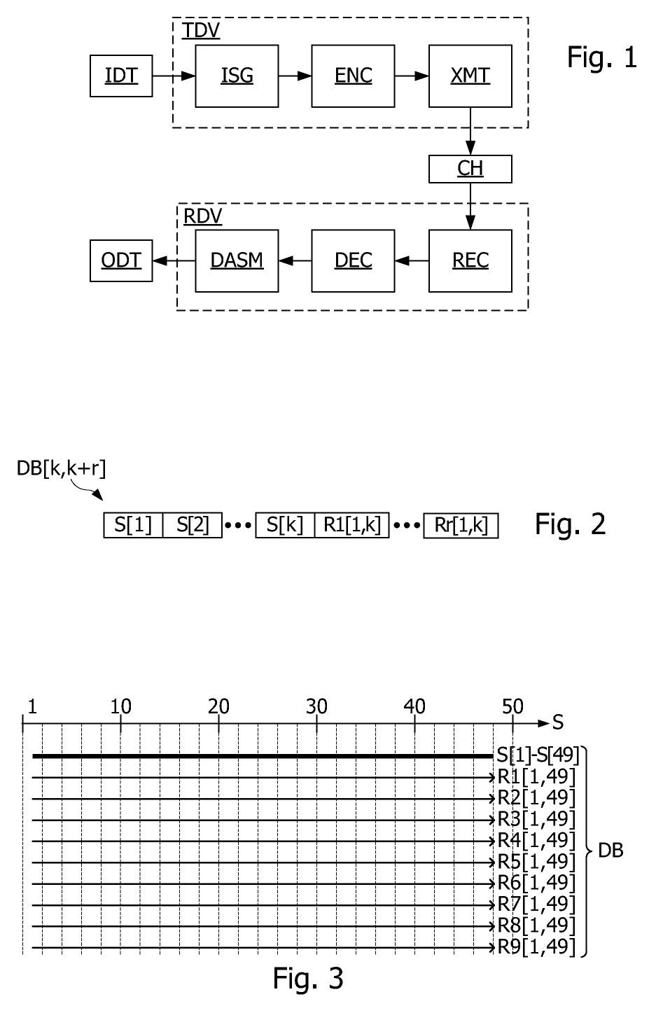

FIG. 1 schematically represents a data transmission system,

FIG. 2 diagrammatically represents a conventional format for transmitting data generated in a transmission device of the transmission system,

FIG. 3 illustrates a method for calculating repair symbols on the format represented in FIG. 2,

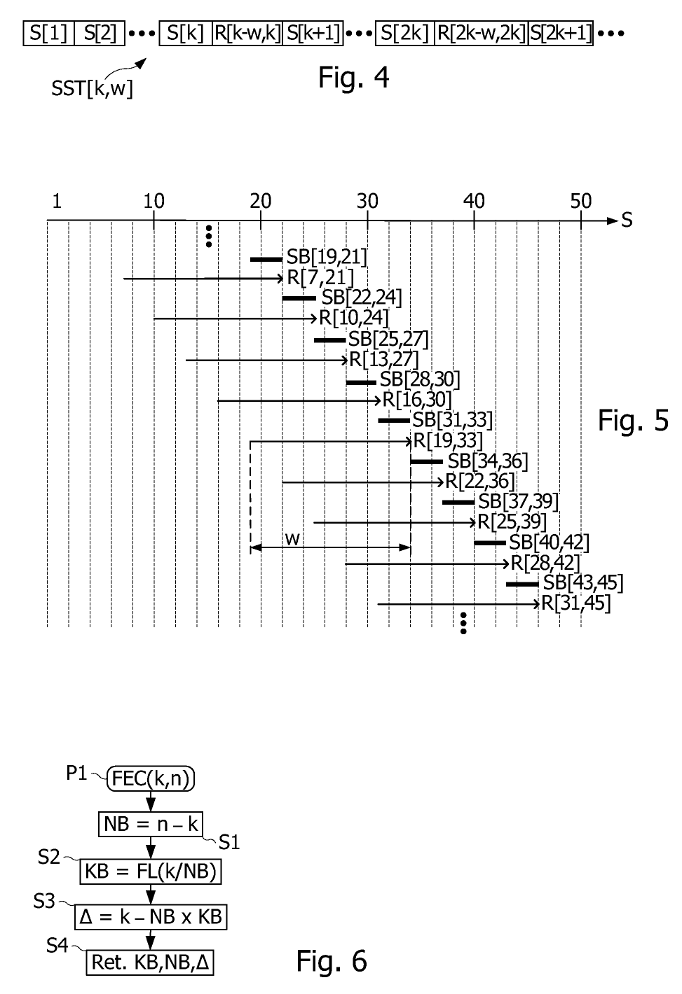

FIG. 4 diagrammatically represents another conventional format for transmitting data generated in the transmission device of the transmission system,

FIG. 5 illustrates a data transmission format and a method for calculating repair symbols on the format shown in FIG. 4,

FIG. 6 represents steps of a procedure for determining a data transmission format, according to an embodiment,

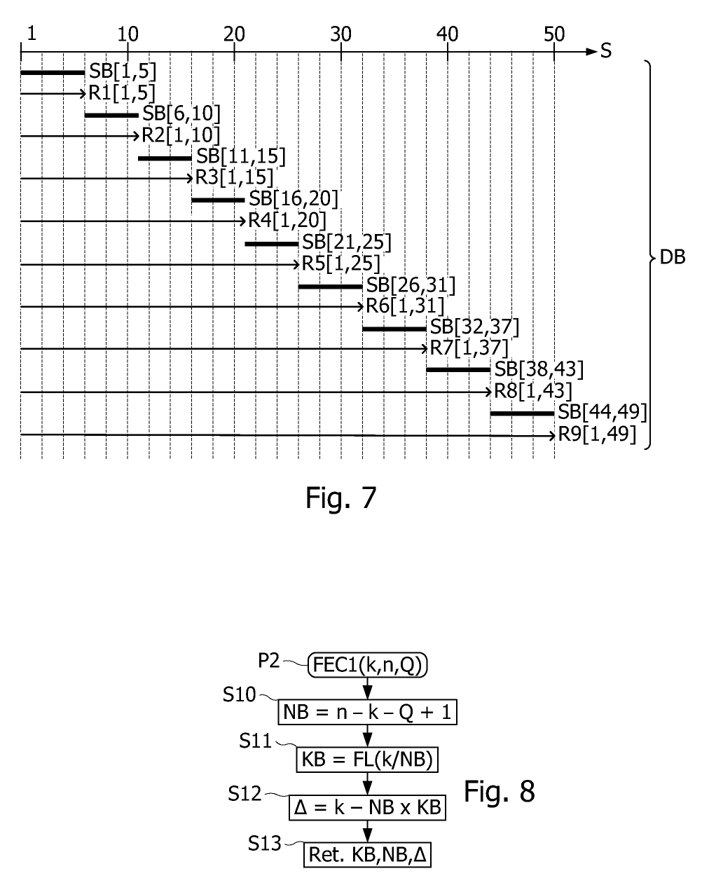

FIG. 7 illustrates an exemplary data transmission format obtained using the procedure shown in FIG. 6,

FIG. 8 represents steps of a procedure for determining a data transmission format, according to another embodiment,

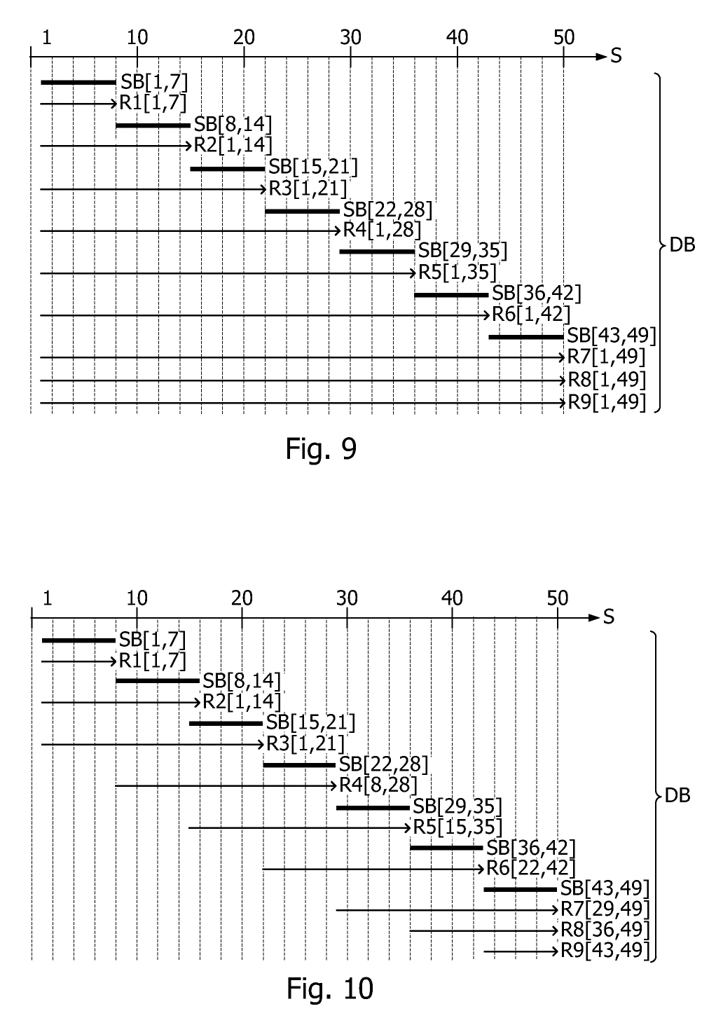

FIGS. 9 to 14 illustrate examples of data transmission formats obtained using the procedure illustrated in FIG. 8, and examples of methods for calculating the repair symbols,

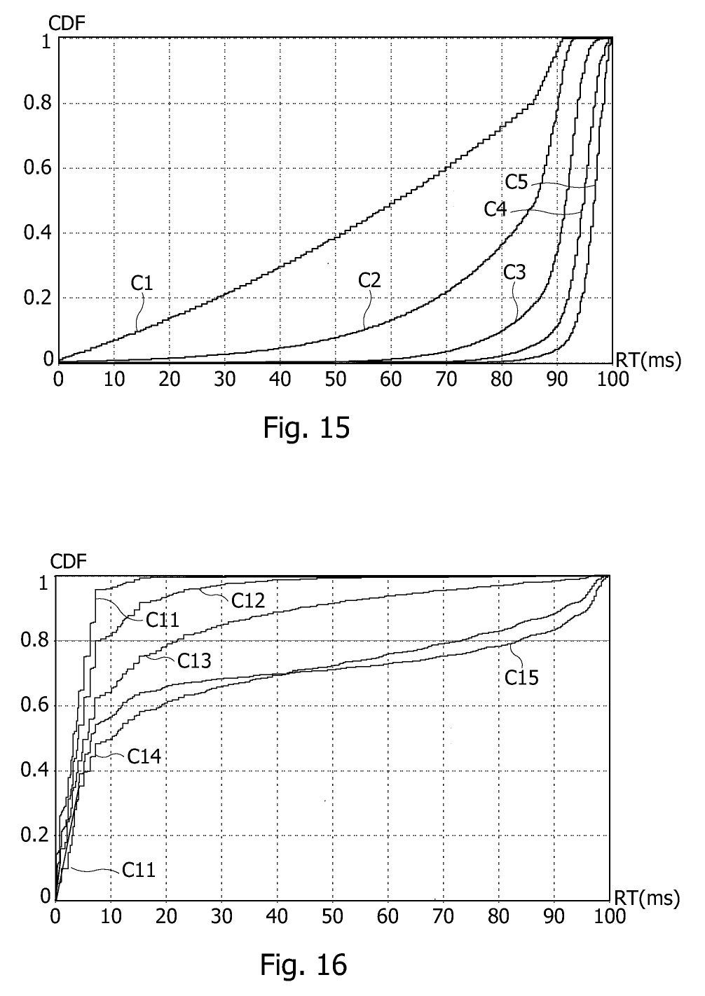

FIGS. 15 to 23 are curves illustrating the performances obtained using the data transmission formats presented above,

FIG. 24 schematically shows a system for delivering content to a plurality of mobile terminals.

FIG. 1 schematically shows a data transmission system. An input data file or stream IDT is provided to a transmitter device TDV configured to transmit the input data IDT to a receiver device RDV over a communication channel CH. The receiver device is configured to provide output data ODT corresponding to the input data. The transmitter device TDV comprises a symbol generator ISG, an encoder module ENC, and an transmission module XMT. The symbol generator ISG is configured to generate source symbols representing the input data IDT, in the form of M-bit binary words. Thus, the input data can be represented as 2^{M} different source symbols. The value of the parameter M is adapted to the communication system. The source symbols produced by the symbol generator ISG are provided to the encoding module ENC for encoding and then supplied to the transmission module XMT. The encoding module ENC is configured to assemble the source symbols into data blocks including repair symbols. The transmission module XMT is configured to format the data of the data blocks received from the encoding module ENC into a transmission format adapted to the transmission channel CH. The transmission channel CH may be a real-time channel, for example a link established through the Internet, or a link for broadcasting content to a plurality of terminals, or a point-to-point link for transmitting voice or video.

The receiver device RDV comprises a reception module REC, a decoding module DEC, and an assembly module DASM for restoring the transmitted data IDT to its initial format. The reception module REC converts the signals transmitted through the transmission channel CH into symbols comprising source symbols and repair symbols. The decoding module DEC detects errors or the possible absence of symbols in the symbols produced by the reception module REC, and attempts to reconstruct any missing or erroneous source symbols using the repair symbols received. For example, errors can be detected using parity bits in transmitted symbols. The assembly module DASM assembles the source symbols provided by the decoder module DEC to generate output data ODT corresponding to the input data IDT transmitted.

FIG. 2 represents a conventional format of a data block DB[k, k+r] that can be provided by the encoding module ENC. The data block DB comprises k source symbols S[1] to S[k], followed by r(=n−k) repair symbols R1[1, k] to Rr[1, k]. FIG. 3 illustrates a method of calculating the repair symbols R1[1, k] to Rr[1, k] in the case of a data block format with k=49 source symbols S[1] to S[49], and r=9 repair symbols. In FIG. 3, each repair symbol R1[1, k] to Rr[1, k] is represented by an arrow extending over all the source symbols from which it is calculated. Thus, each of the repair symbols R1[1, 49] to R9[1, 49] is calculated from the 49 source symbols of the data block DB[49, 58]. The repair symbols Rp[i, j] can be calculated by a respective linear combination of the source symbols, by the following equation:

$$Rp [ i , j ] = {\sum }_{I = i}^{j} {α}_{pl} S [ 1 ] \qquad ( 1 )$$

in which αₚₗ represents randomly chosen coefficients in the field GF(2^{m}), with m=8, for example, and p is between 1 and (n−k). The coefficients αₚₗ can be gathered in a matrix of size k×(n−k), the coefficients αₚₗ of the source symbols S[1] not taken into account in the calculation of the repair symbol Rp being zero. In this case, the repair symbols can be obtained by the following equation:

$$Rp = {\sum }_{I = 1}^{k} {α}_{pl} S [ 1 ] \qquad ( 2 )$$

The matrix of coefficients αₚₗ and parameters defining the format of the transmitted data blocks can be transmitted to the decoding module DEC.

In the example of FIG. 3, if one of the first source symbols S[i] is lost or erroneous, it is necessary to wait for the reception of at least the first repair symbol R1[1, 49] (if the received data block DB has no further errors), to be able to restore the lost or erroneous source symbol. Indeed, it is necessary to have at least one repair symbol for each source symbol to restore, for such a restoration to be possible through the resolution of a system of x equations with x unknowns (x being the number of source symbols to be restored). Thus, the coding format illustrated in FIGS. 2 and 3 makes it possible to restore at most 9 source symbols that are erroneous or lost in a data block of 49 source symbols. Furthermore, the access delay to a stream of data blocks B[49, 58] may be close to the transmission time of two data blocks if the time of access to the stream implies a number of source symbols that are missing or erroneous greater than r=9 in a first received data block, and if at least one error is detected in a second received data block.

FIG. 4 represents another conventional format of a symbol stream SST[k, w] that can be provided by the encoding module ENC. The symbol flow comprises a succession of groups of k source symbols S[1] to S[k], S[k+1] to S[2k], . . . , S[(n−1)k+1] to S[n·k], . . . , each group being followed by a repair symbol R1[k−w, k], R1[2k−w, 2k], . . . , R1[n·k−w, n·k], . . . , calculated on the w previous source symbols in the data stream, with w>k.

FIG. 5 illustrates a method of calculating the repair symbols R1[n·k−w, n·k] (with n=1, 2, . . . ), for a data stream SST[3,15], i.e. wherein the repair symbols are calculated from source symbols belonging to a sliding window of w (=15) source symbols S and a repair symbol is issued after a group SB[n·k−2, n·k] of k (=3) source symbols. In FIG. 5, each repair symbol R[xw, x] is represented by an arrow extending over the w source symbols from which it is calculated. Thus, the repair symbol R[7, 21] is transmitted after the source symbol group SB[18, 21] and is calculated from the source symbols S[7] to S[21]. The next repair symbol R[10, 24] in the stream SST[3, 15] is transmitted after the source symbol group SB[21, 24] and is calculated from the source symbols S[10] to S[24 ]. The repair symbols R[i, j] can also be calculated by equation (1) or (2).

In the example of FIG. 5, it is possible to restore a lost or erroneous source symbol upon receipt of the next repair symbol. The latency for restoring a source symbol is therefore less than the reception time of k=3 source symbols. The access delay to a first source symbol of a stream SST[3, 15] is at least equal to the reception duration of w=15 symbols, if a source symbol is missing in the first group of 3 source symbols received. Moreover, the access delay to a source symbol of the stream can be infinite, if the transmission of the stream produces at least one error in each of the successive groups SB[n·k−2, n·k] of 3 source symbols over which the repair symbols are calculated.

According to an embodiment, the restoration and access latencies are reduced by dividing the data stream in data blocks and dividing each transmitted data block into sub-blocks and assigning to each sub-block of a data block a repair symbol that is transmitted immediately following the last source symbol of the sub-block. Any remaining repair symbols are transmitted after the last sub-block of the data block.

FIG. 6 represents steps S1 to S4 of a procedure P1 for defining a data block format, according to an embodiment. In particular, the procedure P1 determines a number of sub-blocks NB and a number of source symbols KB per sub-block. The procedure P1 can be implemented in the encoding module ENC. The procedure P1 is based on a division of a data block into a number of sub-blocks equal to the number of repair symbols allocated to the data block. Procedure P1 receives as input the number of source symbols k present in the data block and the total number n of symbols in the data block, including repair symbols. In step S1, the number of sub-blocks NB is set equal to the number of repair symbols allocated to the data block, i.e. n−k. In step S2, the number KB of source symbols per sub-block of the data block is calculated by the following equation:

KB=FL(k/(n−k)) (3)

where the function FL(x) provides the largest integer less than or equal to the number x. In step S3, a difference Δ between the number k of source symbols in the data block and the product of the numbers KB and NB is calculated. The number Δ represents the number of remaining source symbols, not assigned to one of the sub-blocks of the data block, if all the sub-blocks of the data block include KB source symbols. The number Δ is used to specify that the division of the data block into sub-blocks comprises Δ sub-blocks of (KB+1) source symbols and (NB−Δ) sub-blocks of KB source symbols. The A sub-blocks of (KB +1) source symbols can be indifferently positioned at the beginning or at the end of the data block. Alternatively, Δ source symbols can be removed from one of the sub-blocks, for example the first or the last sub-block of the data block. In step S4, the procedure P1 ends by providing the numbers KB, NB and Δ. The procedure P1 thus results in a division of each data block into Δ sub-blocks of (KB+1) source symbols and (NB−Δ) sub-blocks SB of KB source symbols.

For example, the data block comprises NB−Δ first sub-blocks SB each grouping KB source symbols from (b·KB+1) to ((b+1)·KB), b varying from 0 to (NB−Δ−2), and Δ last sub-blocks SB each grouping (KB+1) source symbols from (b·KB+b−NB+Δ−1) to ((b+1)·KB+b−NB+Δ), b varying from (NB−Δ−1) to (NB−1).

Thus, the latency of repair or access to the data stream, in the event of loss of p source symbols (p<n−k) in a data block, is less than the reception time of the p repair symbols R[i , j] following the data block. Of course, if the number of source symbols lost in a data block is greater than the number (n−k) of repair symbols per data block, the data block being received is not repairable; it is therefore necessary to wait for the reception of the next data block.

FIG. 7 represents an exemplary format of a data block DB defined by the procedure P1 and a method of calculating the repair symbols. In this example, the data block comprises k=49 source symbols for a total of n=58 symbols, i.e. n−k=9 repair symbols R1 to R9. The procedure P1 defines a division of the data block DB into NB=9 sub-blocks each including KB=5 source symbols, with a difference of Δ=4 source symbols to be distributed in some of the sub-blocks. The Δ (=4) source symbols to be distributed in the sub-blocks can be added for example to the last 4 sub-blocks of the data block DB. As a result, the data block DB includes sub-blocks SB[1-5] (including the source symbols 1 to 5 of the data block DB), SB[6-10], SB[11-15], SB[16-20], SB[21-25], each including 5 source symbols, and the sub-blocks SB[26-31], SB[32-37], SB[38-43] and SB[44- 49], each including 6 source symbols. The first repair symbol R1[1, 5], obtained by a linear combination of the source symbols S[1] to S[5], is transmitted immediately after the first sub-block SB[1-5], thus after the source symbol S[5]. The second repair symbol R1[1, 10], obtained by a linear combination of the source symbols S[1] to S[10], is transmitted immediately after the second sub-block SB[6-10], and so on.

In the example of FIG. 7, the latency of repair or access to the data stream, in the event of the loss of a source symbol, is less than the reception time of 5 source symbols and the repair symbol that follows.

It should be noted that in the example of FIG. 7, the source symbols S[1] to S[5] of the first sub-block SB[1, 5] are protected by all the repair symbols R1-R9 assigned to the data block DB. On the other hand, the source symbols S[44] to S[49] of the last sub-block SB[44, 49] are protected only by the last repair symbol R9. It may therefore be desirable to increase the number of source symbol repair symbols protecting the last sub-block SB[44, 49] of the data block DB. For this purpose, FIG. 8 shows steps S10 to S13 of a procedure P2 for determining a data block format, according to another embodiment. In particular, the procedure P2 determines the number NB of sub-blocks SB per data block and the number of source symbols KB per sub-block from the number k of source symbols per data block, the total number n of symbols by data block, and a number Q of repair symbols to be assigned to the last sub-block of each data block. The parameters KB and NB provided by the procedure P1 (FIG. 6) are then considered as a minimum value for the number KB and a maximum value for the number NB. In the procedure P1, the number Q of repair symbols allocated to the last sub-block is set to 1.

In step S10, the number NB of sub-blocks is calculated by subtracting the quantity Q−1 from the number n−k of repair symbols per data block. In step S11, the number KB of source symbols is calculated by dividing the number k of source symbols per data block by the number NB of sub-blocks obtained in step S10. The number KB is set equal to the largest integer less than the result of division k/NB. Thus, the numbers NB and KB are obtained by the following equations:

NB=n−k−Q+1, KB=FL(k/NB) (4)

In step S12, the difference Δ between the number k of source symbols in the data block and the product of the numbers KB and NB is calculated. Thus, the number Δ is equal to k−NB×KB. In step S13, the procedure P2 returns the numbers KB, NB and Δ thus calculated. Thus, the procedure P2 defines a division of a data block of k source symbols and (n−k) repair symbols, including for example (NB−Δ) sub-blocks of KB source symbols and Δ sub-blocks of (KB+1) source symbols, each sub-block being followed by a repair symbol R[i, j] calculated over at least a portion of the previous source symbols in the data block, for example by the equation (1) or (2). The parameters KB, NB and Δ thus calculated can be transmitted to the decoding module DEC so that it can locate the sub-blocks and the repair symbols in the transmitted data blocks.

If the parameter Q is set to 1, the procedure P2 provides a number NB of sub-blocks equal to n−k (number of repair symbols in a data block), and a number KB of source symbols per sub-block equal to FL(k/(n−k)), according to the format defined by the procedure P1. In the example with k=49 and n=58, the procedure P2 provides a number NB of sub-blocks equal to 9, and a number KB of source symbols per sub-block equal to 5 with a difference Δ equal to 4. The data block format of FIG. 7 is thus achieved. If the parameter Q is set to n−k, the procedure P2 provides a number NB of sub-blocks SB equal to 1, and therefore a number KB of source symbols per sub-block equal to the number k of source symbols in the data block. The format of FIG. 3 is thus achieved, without division of the data block into sub-blocks.

Of course, it may be provided that the number NB of sub-blocks in each data block is fixed, and thus provided at the input of the procedure P2. In this case, step S10 is replaced by a step of calculating the number r of repair symbols per data block, or the total number n of symbols per data block. Thus, the number r of repair symbols per data block is equal to the number NB of sub-blocks per data block plus the number Q−1 of repair symbols to be added at the end of the data block, not counting the repair symbol assigned to the last sub-block of the data block. In step S13, the procedure P2 then provides the number r of repair symbols or the total number n of symbols per data block, instead of the number NB of sub-blocks per data block. It may also be provided to set the number r of repair symbols per data block at a fixed value and to determine the number Q of repair symbols at the end of the data block, depending on the number r and the number NB of sub-blocks per data block.

FIG. 9 represents an exemplary format of a data block DB with 49 source symbols and 9 repair symbols, obtained by the procedure P2. In this example, the number Q of repair symbols at the end of the data block DB is chosen equal to 3. The procedure P2 defines a division of the data block DB into NB=7 sub-blocks each comprising KB=7 source symbols, the difference Δ being zero. The data block DB of FIG. 9 thus includes sub-blocks SB[1, 7], SB[8, 14], SB[15, 21], SB[22, 28], SB[29, 35], SB[36, 42] and SB[42, 49], each sub-block being immediately followed by a repair symbol, respectively R1[1, 7], R2[1, 14], R3[1, 21], R4[1, 28], R5[1, 35], R6[1, 42] and R7[1, 49]. The last sub-block SB[42, 49] is followed by three repair symbols R7[1, 49], R8[1, 49] and R9[1, 49], according to the parameter Q chosen equal to 3.

Thus, the latency of repair or access to such a data block, in case of loss of a source symbol, is less than or equal to the reception time of 7 source symbols plus a repair symbol.

It should be noted in the examples of FIGS. 7 and 9 that the source symbols of the first sub-block SB[1, 5], SB[1, 7] are protected by all the repair symbols allocated to the data block DB. On the other hand, the last sub-block SB[44, 49], SB[43, 49] of the data block DB is protected by only one repair symbol R9[1, 49] in the example of the FIG. 7, and by the three repair symbols R7[1, 49], R8[1, 49] and R9[1, 49] in the example of FIG. 9. As a result, if the number of source symbols lost at the beginning of the block is greater than the number of repair symbols, it is not possible to restore the lost source symbols of the data block DB, and requires waiting for the reception of the source symbols of the next data block.

It may be desirable to standardize the number of repair symbols protecting each source symbol in the data block. For this purpose, consider for example the case where the data block is divided into NB sub-blocks with the NB−Δ first sub-blocks SB each including KB source symbols from (b·KB+1) to ((b+1)·KB), b varying from 0 to (NB−Δ−2), and the Δ last sub-blocks SB each including (KB+1) source symbols from (b·KB+b−NB+Δ−1) to ((b+1)·KB+b−NB+Δ), b varying from (NB−Δ−1) to (NB−1). The last NB−1 repair symbols can be calculated over the source symbols from (b·KB+1) to k, when b is less than (NB−Δ−1), and (b·KB+b−NB+Δ−1) to k, when b is greater than (NB−Δ−2). As the number of source symbols from which some repair symbols are calculated is reduced, the calculation of the repair symbols and the restoration calculations of a source symbol are simplified.

Thus, FIG. 10 shows an exemplary format of a data block DB with 49 source symbols and 9 repair symbols, derived from the format of FIG. 9, and in which each source symbol is protected by Q (=3) repair symbols. The size and distribution of the sub-blocks in the data block DB is unchanged from the format shown in FIG. 9. The repair symbols R1 to R3 are always calculated from the first source symbol S[1] of the data block DB. On the other hand, the repair symbols R4[8, 28], R5[15, 35], R6[22, 42] and R7[29, 49] are calculated from the 21 preceding source symbols, the repair symbol R8[36, 49] is calculated from the last 14 source symbols S[36] to S[49] of the data block DB, and the repair symbol R9[43, 49] is calculated from the last 7 source symbols S[ 43] to S[49] of the data block DB.

In the example of FIG. 10, if more than three source symbols are lost in the first sub-block SB[1, 7] of the data block DB, it is not possible to restore the lost source symbols. On the other hand, it is possible to restore a source symbol lost in the following three sub-blocks SB[8, 14], SB[15, 21], SB[22, 28] as soon as the repair symbol R4[8, 28] is received, which does not require knowledge of the symbols of the first sub-block then considered as lost.

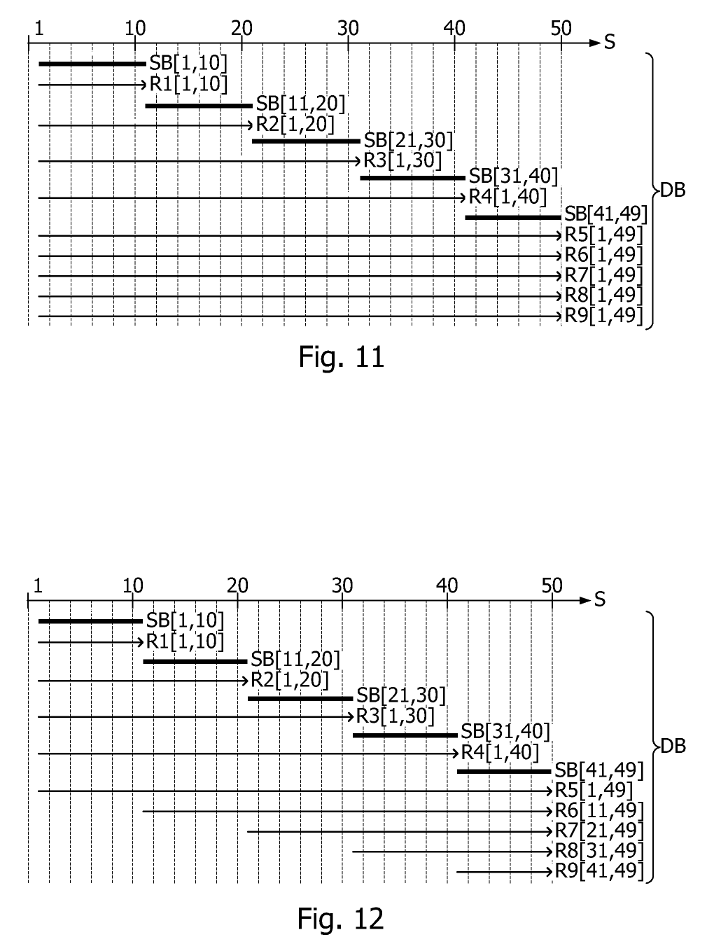

FIG. 11 shows an exemplary format of a data block DB with 49 source symbols and 9 repair symbols, obtained by the procedure P2. In this example, the number Q of repair symbols at the end of the data block DB is chosen equal to CL((n−k)/2), i.e. 5, the function CL(x) representing the smallest integer greater than or equal to the number x. The procedure P2 defines a division of the data block DB into NB=5 sub-blocks, each including KB=9 source symbols, the difference Δ being equal to 4. As a consequence, the choice of Q set at 5 results in a division of the data block DB into a sub-block of 9 source symbols and 4 sub-blocks of 10 source symbols. Thus, the data block DB of FIG. 11 includes 4 sub-blocks SB[1, 10], SB[11, 20], SB[21, 30], SB[31, 40] of 10 source symbols and one sub-block SB[41, 49] of 9 source symbols, each sub-block being immediately followed by a repair symbol R1[1, 10], R2[1, 20], R3[1, 30], R4[1, 40] and R5[1, 49]. The last sub-block SB[41, 49] is followed by five repair symbols R5[1, 49], R6[1, 49], R7[1, 49], R8[1, 49] and R9[1, 49], according to the parameter Q chosen equal to 5.

As before, it is possible in this format to standardize the number of repair symbols per source symbol. Thus, FIG. 12 shows an exemplary format of a data block DB with 49 source symbols and 9 repair symbols, derived from the format of FIG. 11, and in which each source symbol is protected by five repair symbols. The size and distribution of the sub-blocks in the data block DB is unchanged from the format shown in FIG. 11. The repair symbols R1 to R5 are all calculated from the first source symbol S[1] of the data block DB. On the other hand, the other repair symbols R6[11, 49], R7[21, 49], R8[31, 49] and R9[41, 49] are respectively calculated from the source symbols S[11], S[21], S[31] and S[41].

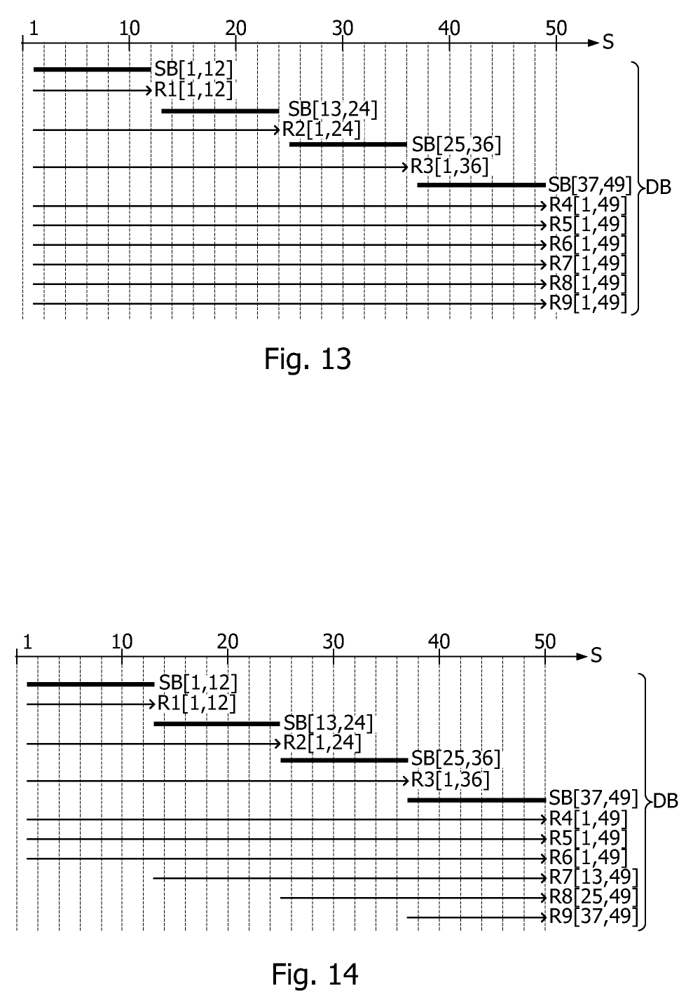

FIG. 13 shows an exemplary format of a data block DB with 49 source symbols and 9 repair symbols, obtained by the procedure P2, when the number Q of repair symbols at the end of the data block DB is chosen equal to 6. The procedure P2 defines a division of the data block DB into NB=4 sub-blocks each including KB=12 source symbols, the number Δ being equal to 1. This distribution therefore implies adding a source symbol in one of the sub-blocks, for example the last sub-block. The data block DB of FIG. 13 thus includes 3 sub-blocks SB[1, 12], SB[13, 24] and SB[25, 36] including 12 source symbols and a sub-block SB[37, 49] of 13 source symbols, each sub-block being immediately followed by a repair symbol R1[1, 12], R2[1, 24], R3[1, 36] and R4[1, 49]. The last sub-block SB[37, 49] is followed by six repair symbols R4[1, 49], R5[1, 49], R6[1, 49], R7[1, 49], R8[1, 49] and R9[1, 49], according to the parameter Q chosen equal to 6.

As before, it is possible in this format to standardize the number of repair symbols per source symbol. Thus, FIG. 14 shows an exemplary format of a data block DB with 49 source symbols and 9 repair symbols, derived from the format of FIG. 13, and in which each source symbol is protected by six repair symbols. The size and distribution of the sub-blocks in the data block DB is unchanged from the format shown in FIG. 13. The repair symbols R1 to R6 are always calculated from the first source symbol S[1] of the data block DB. On the other hand, the other repair symbols R7[13, 49], R8[25, 49] and R9[37, 49] are calculated from the source symbols S[13], S[25] and S[37], respectively.

FIGS. 15 to 18 show variation curves of the probability of lost symbol repair times RT, for different data block formats. These curves were obtained by simulating a transmission of blocks of 100 source symbols and 125 symbols in total, with a bit rate of 1 Mb/s. The transmission time was set at 100 ms. Each measurement was obtained by simulating the transmission of 107 source symbols, i.e. 105 blocks of data. Symbol losses are obtained from a Bernoulli loss model. The repair time of a source symbol corresponds to the time between the moment when the source symbol should have been received in the absence of an error and the moment when the source symbol is restored.

FIG. 15 shows curves C1 to C5 of variation of the repair probability as a function of the repair time, when all the repair symbols are transmitted at the end of the data block (FIG. 3). Curves C1 to C5 were obtained with symbol loss rates at 1, 5, 10, 15 and 20%, respectively. From curve C1, the repair probability reaches 0.4 and 1, for repair times of about 50 ms and 90 ms, respectively. The lost symbol repair time gradually increases as the symbol loss rate increases. Thus, according to curve C2, the repair time reaches about 82 ms and 92 ms with probabilities of 0.4 and 1, respectively. From curve C3, the repair time increases to about 91 ms and 96 ms, with probabilities of 0.4 and 1, respectively. From curve C4, the repair time increases to about 94 ms and 98 ms, with probabilities of 0.4 and 1, respectively. From curve C5, the repair time increases to about 96 ms and 100 ms with probabilities of 0.4 and 1, respectively.

FIG. 16 shows curves C11 to C15 of variation of the repair probability of lost symbols as a function of the repair time, when the format of the data blocks transmitted includes as many sub-blocks as repair symbols at the end of the data 1 block, and when all the sub-blocks are protected substantially by the same number of repair symbols (FIG. 12). Curves C11 to C15 were obtained with symbol loss rates of 1, 5, 10, 15 and 20%, respectively. From curves C11 to C15, the lost symbol repair time is between about 3 and 7 ms, with a probability of 0.4. From curve C11, the repair probability is 1 for a lost symbol repair time of approximately 16 ms. This repair time increases gradually as the symbol loss rate increases. Thus, according to the curve C12, the lost symbol repair time reaches about 50 ms with a probability close to 1. From curve C13, this repair time increases to approximately 50 ms and 96 ms with probabilities of 0.9 and 1, respectively. From curve C14, the lost symbol repair time increases to about 74 ms and 98 ms with probabilities of 0.8 and 1, respectively. From curve C15, the lost symbol repair time increases to approximately 84 ms and 98 ms with probabilities of 0.8 and 1, respectively. The format of FIG. 12 thus displays much better performance in terms of lost symbol repair latency than the conventional format of FIG. 3.

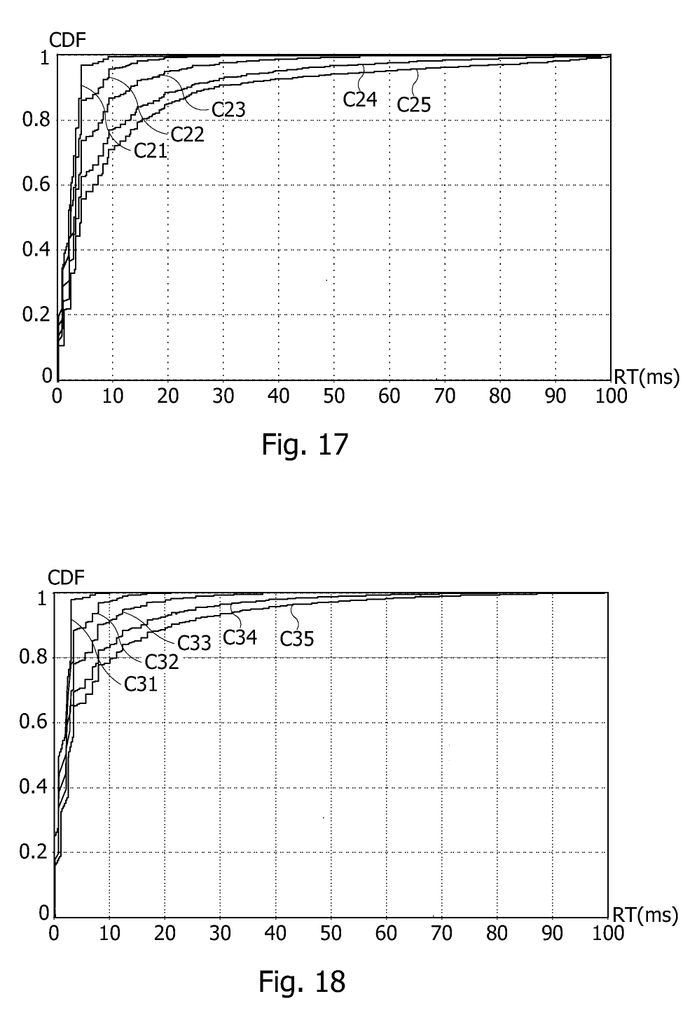

FIG. 17 shows curves C21 to C25 of variation in the probability of repairing lost symbols as a function of the repair time, when the format of the transmitted data blocks includes two or three repair symbols at the end of the data block (FIG. 9 or 10). Curves C21 to C25 were obtained with symbol loss rates of 1, 5, 10, 15 and 20%, respectively. From curves C21 to C25, the repair time is less than about 7 ms, with a probability of 0.6. From curve C21, the repair probability is 1 at about 10 ms. The repair time increases gradually as the symbol loss rate increases. According to the curve C22, the repair time reaches about 20 ms with a probability close to 1. From curve C23, the repair time is approximately 46 ms with a probability of 1. According to curve C24, the repair time increases to about 80 ms with a probability of 1. According to curve C25, the repair time is less than 70 ms when the probability is greater than 0.95, and reaches 98 ms with a probability of 1. The format of FIG. 9 or 10 therefore has better performance in terms of repair latency than the format of FIG. 12.

FIG. 18 shows curves C31 to C35 of variation in the probability of repairing lost symbols as a function of the repair time, when the format of the data blocks transmitted includes as many sub-blocks as repair symbols (FIG. 7). Curves C31 to C35 were obtained with symbol loss rates at 1, 5, 10, 15 and 20%, respectively. From curves C31 to C35, the repair time is less than about 10 ms, with a probability of 0.8. From curve C31, the repair probability is 1 at about 7 ms. The repair time increases gradually as the rate of symbol loss increases. According to the curve C32, the lost symbol repair time reaches about 20 ms with a probability close to 1. According to curve C33, this repair time increases to about 34 ms with a probability of 1. According to curve C34, this repair time increases to about 56 ms with a probability of 1. According to curve C35, this repair time is less than 30 ms when the probability is greater than 0.95, and reaches 74 ms with a probability of 1. The format of FIG. 7 therefore has better performance in terms of repair latency than the format of FIG. 9 or 10.

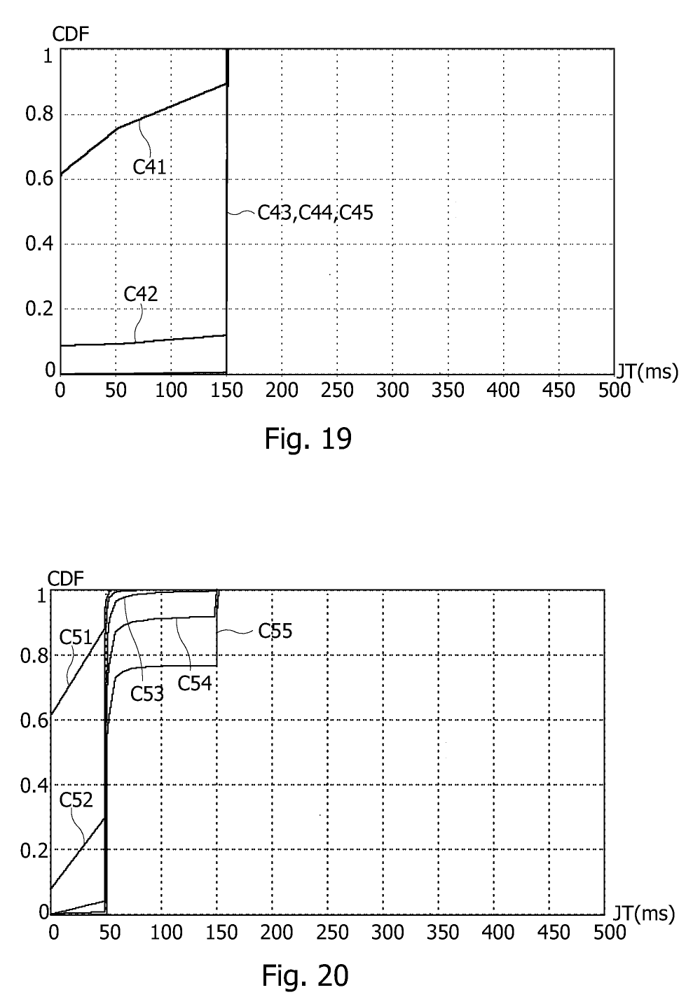

FIGS. 19 to 23 show curves of variation of the access delay probability to a data stream, for different data block formats. These curves were also obtained by simulating a block transmission of 100 source symbols and 125 symbols in total, with a bit rate of 1 Mb/s. The transmission time was set at 100 ms. Each measurement was obtained by simulating the transmission of 107 source symbols, i.e. 105 blocks of data. Symbol losses are obtained from a Bernoulli loss model. The access delay to the data stream is calculated by considering that the flow access time occurs at the 50th source symbol of the second transmitted data block. In the absence of symbol loss between the time of access to the data stream and the moment of reception of the last symbol of the first data block received, or of the sliding window, the access delay to the stream is fixed at 0 ms. FIG. 19 shows curves C41 to C45 of variation of the access delay probability to the data flow, when the format of the transmitted data blocks includes a single sub-block, all the repair symbols being transmitted at the end of the data block (FIG. 3). Curves C41 to C45 were obtained with symbol loss rates at 1, 5, 10, 15 and 20%, respectively. Curves C41 to C45 show that the access delay does not exceed about 150 ms (reached with a probability of 1). According to the curve C41, the access delay is zero with a probability slightly greater than 0.6. The access delay reaches 50 ms with a probability of about 0.75, and reaches 150 ms with a probability greater than 0.85. From curve C42, the access delay to the data stream is less than 150 ms with a probability of less than about 0.12. According to the curves C43 to C45, the access delay is less than 150 ms with a probability close to 0.

FIG. 20 shows curves C51 to C55 of variation of the access delay probability, when the format of the data blocks transmitted includes as many sub-blocks as repair symbols grouped at the end of the data block (FIG. 12). Curves C51 to C55 were obtained with symbol loss rates at 1, 5, 10, 15 and 20%, respectively. From curves C51 to C55, the access delay is less than about 50 ms, with a probability greater than 0.75. According to the curve C51, the access delay is zero with a probability close to 0.6. According to the curves C51, C52, an access delay of 50 ms is reached with a probability close to 1. From curve C53, the probability of 1 is reached with an access delay of about 100 ms. From curves C54 and C55, the probability of 1 is reached with an access delay of about 150 ms. According to the curve C54, the access delay is between 50 and 150 ms with a probability greater than 0.9. From curve C55, the access delay is between 50 and 150 ms with a probability higher than 0.75. The format of FIG. 9 or 10 therefore has better performance in terms of access latency than the format of FIG. 3.

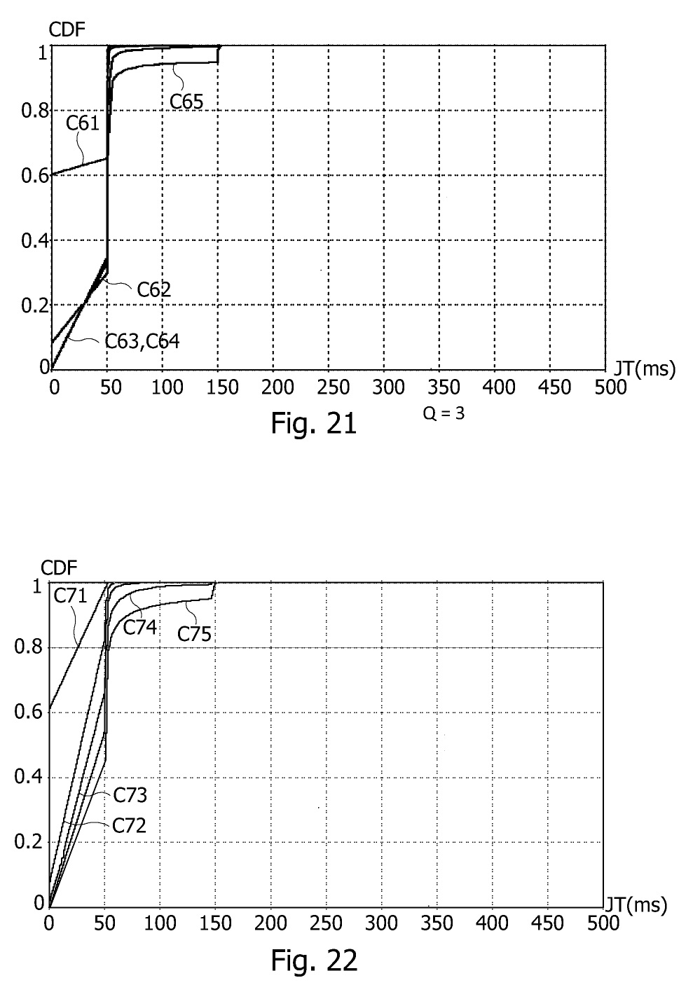

FIG. 21 shows curves of variation C61 to C65 of the access delay probability, when the format of the transmitted data blocks includes two or three repair symbols at the end of the data block (FIG. 9 or 10). Curves C61 to C65 were obtained with symbol loss rates at 1, 5, 10, 15 and 20%, respectively. From curves C61 to C65, the access delay is less than about 50 ms, with a probability greater than 0.9. According to the curve C61, the access delay is zero with a probability close to 0.6. According to the curves C61, C62, C63, an access delay of 50 ms is reached with a probability close to 1. From curve C64, a probability of 1 is reached with an access delay of about 130 ms. According to curve C65, the access delay increases to about 150 ms with a probability greater than 0.95. The format of FIG. 9 or 10 therefore has better performance in terms of access latency than the format of FIG. 11 or 12.

FIG. 22 shows curves C71 to C75 of variation of the access delay probability, when the format of the transmitted data blocks includes as many sub-blocks as repair symbols (FIG. 7). Curves C71 to C75 were obtained with symbol loss rates at 1, 5, 10, 15 and 20%, respectively. From curves C71 to C75, the access delay is less than about 50 ms, with a probability greater than 0.95. According to the curve C71, the access delay is zero with a probability close to 0.6. According to the curves C71, C72, an access delay of 50 ms is reached with a probability close to 1. From curve C73, the probability of 1 is reached with an access delay of about 70 ms. From curves C74, C75, the probability of 1 is reached with an access delay of about 150 ms. According to curve C74, the access delay is between 50 and 150 ms with a probability greater than 0.9. According to curve C75, the access time is between 50 and 150 ms with a probability greater than 0.8. The format of FIG. 7 therefore has better performance in terms of access latency than the format of FIG. 9 or 10.

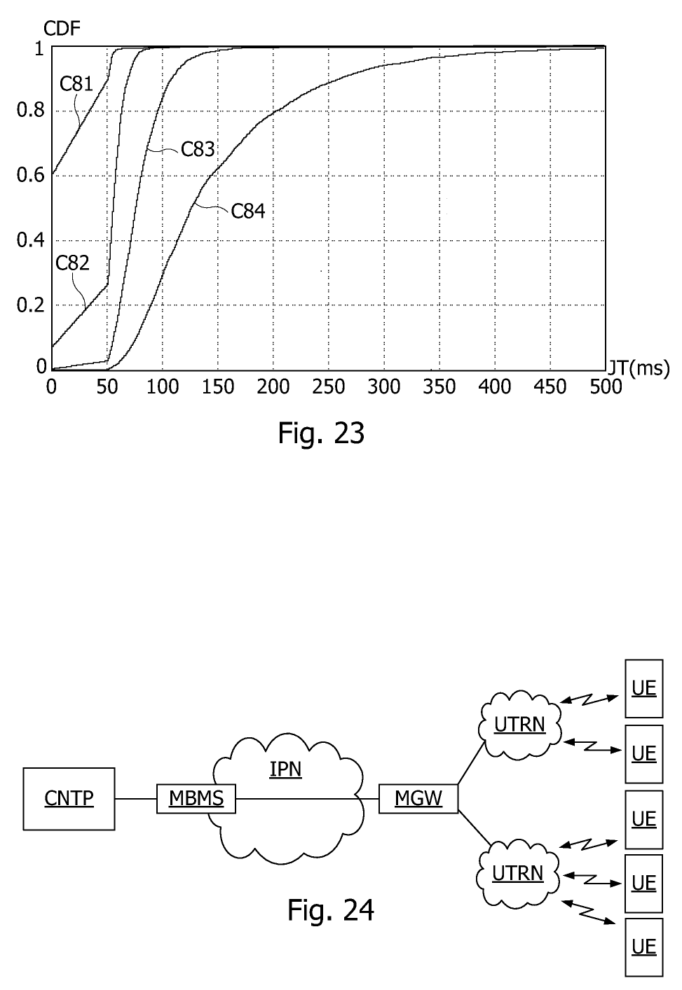

From the curves of FIGS. 19 to 22, the access delay JT to a data stream is capped to a value less than about 150 ms when the data is organized into data blocks. FIG. 23 shows curves C81 to C84 of variation of the access latency probability, when the format of the data blocks transmitted is in the form of that of FIG. 5 with a window w of 50 source symbols. Curves C81 to C84 were obtained with symbol loss rates at 1, 5, 10 and 15%, respectively. At symbol loss rates of 20% and above, the access delay to the data stream tends to infinity. According to the curve C81, the access delay is zero with a probability close to 0.6, and slightly greater than 50 ms with a probability of 1. The curve C82 reaches a probability close to 1, with an access delay of about 80 ms. From the curve C83, a probability close to 1 is reached with an access delay of about 150 ms. According to curve C84, a probability close to 1 is reached with an access delay of about 500 ms. The format of FIG. 5 therefore achieves poorer performance in terms of access latency than the other formats studied.

According to an embodiment, a content server including or coupled to the transmitter device TDV, multi-casts content to a set of terminals such as mobile terminals, including the receiver device RDV. Thus, FIG. 24 represents an example of such a content server CNTP connected to a network IPN, such as the Internet network, via a server MBMS implementing a Multimedia Broadcast Multicast Service (MBMS) or an eMBMS service (enhanced MBMS). The terminals UE are each connected to mobile networks UTRN, which are connected to the network IPN via gateways MGW. The content provided by the server CNTP is broadcast in accordance with one of the formats described above. Some of the terminals UE with poor reception conditions may send on a return channel a return message signaling poor reception conditions to the content server CNTP. Thus, the return message may indicate a packet loss rate, a residual loss rate after using the repair symbols, and other features relating to the quality of the received signal.

In response, the content server CNTP sends to terminals that have reported poor reception conditions, on unicast channels, one or more additional repair symbols for each data block sent by the transmitter device TDV of the content server CNTP for a period of time. Thus, the content server CNTP can transmit multi-cast content to several tens of thousands of terminals UE, and transmit in, point-to-point mode, additional repair symbols to several hundred terminals UE reporting bad reception quality conditions. These provisions make it possible to provide a multi-cast content service, while guaranteeing reception quality, without using a large bandwidth on point-to-point channels, since only repair symbols are transmitted by these channels.

The sending to the server by a terminal of a return message indicating good reception conditions may terminate the sending of additional repair symbols for this terminal. In addition to this sending being stopped at the end of the transmission of the broadcasted content, it may also be terminated at the end of a certain period. The terminals then always have the possibility of sending new return messages signaling poor reception conditions, to trigger again the sending of additional repair symbols in point-to-point transmission mode.

Note that the processing of the signaling messages of good or bad reception conditions, and the transmission of additional repair symbols, may be performed by a server other than the content server CNTP, for example a server such as the MBMS server, ensuring the broadcasting of the content to terminals UE. Furthermore, the multi-cast service can be implemented by other means and other protocols than those illustrated by way of example in FIG. 24. For example, the multi-cast service can be implemented in a Wi-Fi network.

It will be apparent to those skilled in the art that the present invention may be subject to various alternative embodiments and various applications. In particular, it can be provided to assign two (or more) repair symbols to each sub-block. However, this solution may be considered as sub-optimal in terms of correction latency, compared to the solution of doubling the number of sub-blocks per block of data and assigning a single repair symbol to each sub-block.

On the other hand, the source symbols from which each of the repair symbols are calculated are not necessarily consecutive in the data block, and do not necessarily include the source symbol transmitted immediately before the repair symbol.

1. A data transmission method, comprising the steps of:
encoding data to be transmitted in the form of source symbols grouped into data blocks,
assigning each data block a number of repair symbols, and for each block of data:
distributing the source symbols of the data block into sub-blocks, the number of sub-blocks being equal to the number of repair symbols allocated to the data block,
assigning a repair symbol to each sub-block of the data block,
calculating the repair symbol of each sub-block of the data block by a linear combination of source symbols of the sub-block and source symbols of preceding sub-blocks in the data block, and
transmitting the data block in a stream of data blocks, successively transmitting each sub-block of the data block, each sub-block being transmitted by transmitting the source symbols of the sub-block, followed by the repair symbol of the sub-block.

2. The method of claim 1, wherein each repair symbol of the data block is computed by a linear combination of at least a portion of the source symbols of the data block, so that each source symbol of the data block is used to calculate a number equal or different by one of repair symbols of the data block.

3. The method of claim 1, wherein each repair symbol of the data block is computed by a linear combination of all previously transmitted source symbols of the data block.

4. The method according to claim 1, wherein a plurality of repair symbols calculated from at least a part of the source symbols of the last sub-block of the data block, are transmitted at the end of the data block.

5. The method according to claim 1, wherein each sub-block of the data block comprises a number equal or different by one of source symbols.

6. The method according to claim 1, wherein the data block comprises as many sub-blocks as repair symbols transmitted at the end of the data block.

7. The method according to claim 1, comprising the following steps for defining a format of the data block:
defining a first number of repair symbols to be transmitted at the end of the data block,
determining a number of sub-blocks of the data block according to the first number and a number of repair symbols assigned to the data block, or determining the number of repair symbols assigned to the data block according to the number of sub-blocks of the data block and the first number,
calculating a minimum number of source symbols per sub-block by dividing the number of source symbols in the data block by the number of sub-blocks, the minimum number of source symbols being set equal to the greatest integer less than or equal to the result obtained from the division, and
calculating a difference between the number of source symbols of the data block and the product of the number of sub-blocks in the data block by the minimum number of source symbols per sub-block, the difference defining a number of source symbols to be added in the sub-blocks of the data block.

8. The method according to claim 7, wherein the difference defines a number of sub-blocks of the data block having a number of source symbols equal to the minimum number of source symbols per sub-block, increased by one.

9. The method according to claim 1, comprising the steps of:
receiving from a user terminal in a point-to-point mode, a message signaling poor reception conditions, and
transmitting to the terminal in point-to-point mode, in response to the message, at least one repair symbol for each data block transmitted after receiving the message.

10. A method for receiving transmitted data according to the transmission method of claim 1, the reception method comprising successive steps of receiving the sub-blocks of source symbols of a data block, the reception of each sub-block being followed by the reception of a repair symbol associated with the sub-block, each repair symbol corresponding to a linear combination of the source symbols of the sub-block associated with the repair symbol.

11. The method according to claim 10, comprising steps of:
detecting a missing or erroneous source symbol in the data block, and
upon receipt of a first repair symbol following the missing or erroneous source symbol, calculating the missing or erroneous source symbol by solving an equation resulting from the equality between the first repair symbol and a linear combination corresponding to the first repair symbol.

12. The method of claim 10, comprising the steps of:
detecting bad reception conditions of data blocks transmitted in a multi-cast mode,
transmitting in a point-to-point mode, to server, a message signaling poor reception conditions, and
receiving in point-to-point mode, for data blocks received in the multi-cast mode, additional repair symbols usable for calculating missing source symbols in the received data blocks.

13. A data transmission device configured to implement the method according to claim 1.

14. A data receiving device configured to implement the method according to claim 10.
